(19) United States
(12) Patent Application Publication
(10) Pub. No.: US 2008/0285370 A1
(43) Pub. Date: Nov. 20, 2008

(54) Semiconductor memory and system

(75) Inventor: Yoshiaki Okuyama, Kirishima (JP)

Correspondence Address: ARENT FOX LLP, 1050 CONNECTICUT AVENUE, N.W., SUITE 400, WASHINGTON, DC, 20036, US

(73) Assignee: FUJITSU LIMITED

(21) Appl. No.: 11/902,841

(22) Filed: Sep. 26, 2007

(30) Foreign Application Priority Data
Sep. 27, 2006 (JP) 2006-262755

(51) Int. Cl. G11C 11/406

(52) U.S. Cl. 365/222; 365/190

(57) ABSTRACT

An access control unit performs an access operation and a refresh operation of a memory block in response to an access request and a refresh request. The access control unit operates respective memory blocks in a single-cell mode or a twin-cell mode according to cell mode information in a mode setting unit. A refresh control unit disables the refresh operation of the memory block the nonperformance of which is set in the mode setting unit. By operating only the memory block requiring high reliability in the twin-cell mode and selectively disabling the refresh operation of the memory block, a semiconductor memory can be operated optimally according to a specification of a system, enabling a reduction in power consumption.

### CROSS REFERENCE TO RELATED APPLICATION

This application is based upon and claims the benefit of priority from Japanese Patent Application No. 2006-262755, filed on Sep. 27, 2006, the entire contents of which are incorporated herein by reference.

### BACKGROUND

1. Field

The present invention relates to a semiconductor memory including dummy memory cells.

2. Description of the Related Art

A semiconductor memory such as a DRAM or a pseudo SRAM periodically needs a refresh operation to retain data written in a dynamic memory cell. Therefore, for example, when the DRAM is used as a work memory of portable equipment, just holding data consumes power even while the portable equipment is not used, and a battery is exhausted.

To reduce power consumption in a standby operation mode (data retention mode) of the DRAM, a twin-cell method and a partial refresh method are proposed (for example, Japanese Unexamined Patent Application Publication No. 2002-170386). In the twin-cell method, complementary data is stored in a pair of memory cells connected to complementary bit lines during the standby operation mode. This makes it possible to lengthen the data retention time of the memory cell and lower the frequency of the refresh operation. In the partial refresh method, by reducing the number of memory cells which retain data during the standby operation mode, the number of times of refresh operation needed to refresh all memory cells can be reduced. Consequently, the power consumption can be reduced.

However, in a semiconductor memory having a conventional twin-cell function, a twin-cell area and a single-cell area cannot be mixed. Further, a conventional partial refresh function is a function effective only during the data retention mode. Therefore, during a normal operation in which an access operation is performed, data in all memory areas are retained.

With an increase in the memory capacity of the semiconductor memory, various kinds of data become able to be stored in one semiconductor memory. In other words, data with different reliability levels or data with different retention times from when they are written into memory cells until they are read therefrom are sometimes stored in one semiconductor memory. Conventionally, even in such a case, the operation mode of the semiconductor memory is set in accordance with data with the highest reliability or data with the longest retention time. For example, if reliability is required, all memory areas need to be operated in a twin-cell mode. However, in the twin-cell mode, the memory capacity of information becomes half. As a result, if a semiconductor memory with a large memory capacity is adopted, the power consumption increases.

The data retention time of the dynamic memory cell is, for example, 50 ms when the refresh operation is not performed. On the other hand, in some systems, about 10 ms is sometimes a sufficient retention time of some kind of data. In this case, the memory cell storing this data need not be refreshed. However, in the conventional semiconductor memory including dynamic memory cells, all memory cells need to be refreshed during the normal operation mode. In particular, the DRAM or pseudo SRAM having an auto refresh mode includes a refresh address counter, and the refresh operation is sequentially performed on all the memory cells during the normal operation mode. The refresh operation is performed on memory cells which need not be refreshed, resulting in wasteful power consumption.

### SUMMARY

An object of the present invention is to operate a semiconductor memory optimally according to a specification of a system to reduce power consumption.

In one aspect of the present invention, an access control unit performs an access operation and a refresh operation of a memory block in response to an access request and a refresh request. Further, the access control unit operates respective memory blocks in a single-cell mode or a twin-cell mode according to cell mode information set in a cell mode part of a mode setting unit. By operating only the memory block requiring high reliability in the twin-cell mode, a memory capacity of a semiconductor memory can be minimized, which can prevent an increase in power consumption. A refresh control unit disables a refresh request of the memory block corresponding to a refresh mode part in which disable is set in the mode setting unit from being supplied to the access control unit. By selectively disabling the refresh operation of the memory block, the power consumption can be reduced. As a result, the semiconductor memory can be operated optimally according to a specification of a system, enabling a reduction in power consumption.

### BRIEF DESCRIPTION OF THE DRAWINGS

FIG. 1 is a block diagram showing a first embodiment of the present invention;

FIG. 2 is an explanatory diagram showing details of a mode register shown in FIG. 1;

FIG. 3 is a block diagram showing details of an address comparison circuit shown in FIG. 1;

FIG. 4 is a block diagram showing details of a word decoder shown in FIG. 1;

FIG. 5 is a block diagram showing details of a memory block shown in FIG. 1;

FIG. 6 is a circuit diagram showing details of a quarter decoder shown in FIG. 4;

FIG. 7 is a circuit diagram showing details of a quarter driver shown in FIG. 4;

FIG. 8 is a block diagram showing a system on which a memory shown in FIG. 1 is mounted;

FIG. 9 is an explanatory diagram showing an example in which an operation mode of the memory shown in FIG. 1 is modified;

FIG. 10 is a timing chart showing a read operation of the memory block set to a single-cell mode;

FIG. 11 is a timing chart showing a read operation of the memory block set to a twin-cell mode;

FIG. 12 is a timing chart showing a refresh operation according to set values of refresh mode bits;

FIG. 13 is a block diagram showing details of a word decoder in a second embodiment of the present invention;

FIG. 14 is a block diagram showing details of a refresh address counter;

FIG. 15 is a block diagram showing details of a twin control circuit shown in FIG. 13;

FIG. 16 is a circuit diagram showing a quarter driver shown in FIG. 13; and

FIG. 17 is a timing chart showing a read operation in a transitional twin-cell mode in the second embodiment.

### DETAILED DESCRIPTION OF THE EMBODIMENTS

Hereinafter, embodiments of the present invention will be described, using the drawings. In the drawings, each signal line shown by the heavy line is constituted of a plurality of lines. Further, part of blocks to which the heavy lines are connected is constituted of a plurality of circuits. Each signal line through which the signal is transmitted is denoted by the same reference symbol as the signal name. Each signal starting with “/” represents negative logic. Signals with “Z”, “X” at the end or before the last number represent positive logic and negative logic, respectively. Each double circle in the drawings represents an external terminal.

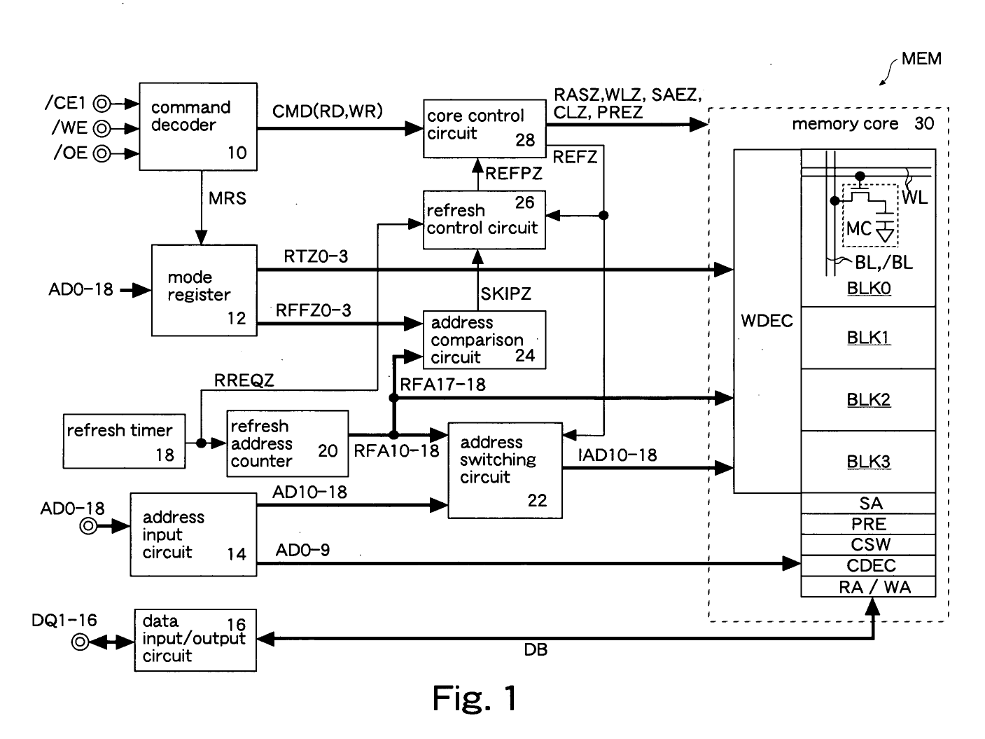

FIG. 1 shows a first embodiment of the present invention. A semiconductor memory MEM is, for example, an FCRAM (Fast Cycle RAM). The FCRAM is a pseudo SRAM including DRAM memory cells and including an SRAM interface. The memory MEM includes a command decoder 10, a mode register 12 (mode setting unit), an address input circuit 14, a data input/output circuit 16, a refresh timer 18 (refresh request generation circuit), a refresh address counter 20, an address switching circuit 22, an address comparison circuit 24, a refresh control circuit 26, a core control circuit 28, and a memory core 30.

The command decoder 10 outputs commands CMD recognized according to logic levels of a chip enable signal /CE1, a write enable signal /WE, and an output enable signal /OE as a read command RD, a write command WR, a mode resister set command MRS, and so on to perform an access operation of the memory core 28. The read command RD and the write command WR are access commands (access requests) to allow the memory core 30 to perform the access operation. The mode register set command MRS is a command to set the mode register 12.

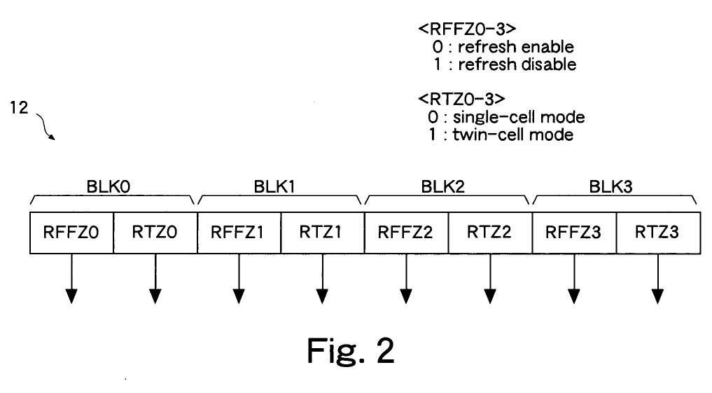

The mode register 12 is set, for example, according to an address signal AD0-18 supplied with the mode register set command MRS. The mode register 12 outputs cell mode signals RTZ0-3 and refresh mode signals RFFZ0-3 according to a set value. Details of the mode register 12 will be described in FIG. 2. The cell mode signals RTZ0-3 are signals indicating operation modes of memory blocks BLK0-3, respectively. The refresh mode signals RFFZ0-3 are signals indicating whether to perform refresh operations of the memory blocks BLK0-3, respectively.

The address input circuit 14 receives the address signal AD0-18 and outputs the received address as a row address signal AD10-18 and a column address signal AD0-9. The row address AD10-18 is used to select the memory block BLK0-3 and the word line WL in the memory block BLK0-3, which will be described later. The column address signal AD0-9 is used to select bit lines BL, /BL.

The data input/output circuit 16 receives a write data signal via data terminals DQ1-16 and outputs the received data signal to a data bus DB. Further, the data input/output circuit 16 receives a read data signal from a memory cell MC via the data bus DB and outputs the received data signal to the data terminals DQ1-16.

The refresh timer 18 includes an oscillator outputting a refresh request signal RREQZ in a predetermined cycle. The refresh address counter 20 sequentially generates a refresh address signal RFA10-18 in response to the refresh request signal RREQZ. The refresh address signal RFA10-18 is an address signal corresponding to the row address signal AD10-18. A Refresh address signal RFA17-18 indicates the memory block BLK0-3 on which the refresh operation is performed, and a refresh address signal RFA10-16 indicates the memory cell MC on which the refresh operation is performed. In other words, the refresh address signal RFA10-18 is a row address signal to select the memory block BLK0-3 and the word line WL.

The address switching circuit 22 selects the refresh address signal RFA10-18 when the refresh operation is performed (REFZ=H), selects the row address signal AD10-18 when the refresh operation is not performed (REFZ=L), and outputs the selected signal as an internal address signal IAD10-18 to the memory core 30.

The address comparison circuit 24 compares the memory block BLK (any of BLK0-3) to be refreshed indicated by the refresh address signal RFA17-18 and the memory block BLK for which disable of the refresh operation is set by the refresh mode signal RFFZ0-3. The address comparison circuit 24 activates a skip signal SKIPZ while the memory block BLK for which the disable of the refresh operation is set is the memory block BLK to be refreshed.

The refresh control circuit 26 outputs a refresh request signal REFPZ in response to the refresh request signal RREQZ. Note, however, that the refresh control circuit 26 masks the output of the refresh request signal REFPZ to the core control circuit 28 during the activation of the skip signal SKIPZ. Namely, the refresh control circuit 26 disables the supply of the refresh request REFPZ to the core control circuit 28 when the memory block BLK indicated by the refresh address signal RFA17-18 and the memory block BLK for which the disable of the refresh operation is set match. The refresh control circuit 26 enables the supply of the refresh request REFPZ to the core control circuit 28 when the memory block BLK indicated by the refresh address signal RFA17-18 and the memory block BLK for which the refresh operation is enabled match. Incidentally, since the memory MEM of this embodiment is the pseudo SRAM, the refresh operation is performed in response to only the refresh request signal RREQZ generated by the refresh timer 18.

The core control circuit 28 outputs a row timing signal RASZ, a word line activation signal WLZ, a sense amplifier activation signal SAEZ, a column control signal CLZ, and a precharge control signal PREZ to allow the memory core 30 to perform a read operation, a write operation, and a refresh operation in response to the read command RD, the write command WR, and the refresh request REFPZ. The row timing signal RASZ is a basic timing signal to control the operation of the memory core 30. The precharge control signal PREZ, the word line activation signal WLZ, the sense amplifier activation signal SAEZ, and the column control signal CLZ are sequentially generated based on the row timing signal RASZ.

The word line activation signal WLZ is a timing signal to control an activation timing of the word line WL. The sense amplifier activation signal SAEZ is a timing signal to control an activation timing of a sense amplifier SA. The column control signal CLZ is a timing signal to control an on-timing of a column switch CSW. The precharge control signal PREZ is a timing signal to control on/off of a precharge circuit PRE.

The core control circuit 28 changes a refresh signal REFZ to a high logic level (H) when the refresh operation is performed, and changes to the refresh signal REFZ to a low logic level (L) when the refresh operation is not performed. The core control circuit 28 includes an arbiter not shown to determine priority between the read command RD and the write command WR, and the refresh request REFPZ. For example, when receiving the read command RD and the refresh request REFPZ at the same time, the operation control circuit 28 gives priority to the refresh request REFPZ. The read operation responsive to the read command RD is held until the refresh operation responsive to the refresh request REFPZ is finished. By contrast, when the refresh request REFPZ is supplied during the read operation, the refresh operation responsive to the refresh request RREQZ is temporarily held, and performed after the read operation is performed.

The memory core 30 includes four memory blocks BLK0-3, a word decoder WDEC, the sense amplifier SA, the precharge circuit PRE, the column switch CSW, a column decoder CDED, a read amplifier RA, and a write amplifier WA. Each memory block BLK0-3 includes plural dynamic memory cells MC, word lines WL connected to the memory cells MC arranged in one direction, and bit lines BL, /BL connected to the memory cells MC arranged in a direction perpendicular to the one direction. The memory cell MC includes a capacitor to retain data as an electric charge and a transfer transistor to connect one end of this capacitor to the bit line BL (or /BL). The other end of the capacitor is connected to a precharge voltage line VPR. A gate of the transfer transistor is connected to the word line WL. Any of the read operation, the write operation, and the refresh operation is performed by the selection of the word line WL.

The word decoder WDEC decodes an internal address signal IAD17-18 (block address signal) to select the memory block BLK0-3 to be accessed. Further, the word decoder WDEC decodes an internal address signal IAD10-16 to select any of the word lines WL. The column address decoder CDEC decodes a column address signal IAD0-9 to select a bit line pair BL, /BL corresponding to the data terminals DQ1-16.

The sense amplifier SA amplifies a difference in signal amount between data signals read to the bit line pair BL, /BL. The precharge circuit PRE supplies a precharge voltage to the bit lines BL, /BL. The column switch CSW connects the bit lines BL, /BL corresponding to the column address signal IAD0-9 to the read amplifier RA and the write amplifier WA. The read amplifier RA amplifies complementary read data outputted via the column switch CSW in a read access operation. The write amplifier WA amplifies complementary write data supplied via the data bus DB and supplies the data to the bit line pair BL, /BL in a write access operation.

Incidentally, the refresh address counter 20, the address comparison circuit 24, and the refresh control circuit 26 function as a refresh control unit which disables the refresh request REFPZ of the memory block BLK for which the disable of the refresh operation is set from being supplied to the core control circuit 28. The core control circuit 28 and the word decoder WDEC function as an access control unit which performs the access operation and the refresh operation of the memory block BLK0-3 in response to the access request RD, WR and the refresh request PREQZ and operates each memory block BLK in a single-cell mode or a twin-cell mode according to the cell mode signals RTZ0-3 (cell mode information) outputted from the mode register 12.

FIG. 2 shows details of the mode register 12 shown in FIG. 1. The mode register 12 includes refresh mode bits RFFZ0-3 (a refresh mode part) and cell mode bits RTZ0-3 (a cell mode part). The refresh mode bits RFFZ0-3 are provided corresponding to the memory blocks BLK0-3, respectively, and refresh mode information indicating the enable/disable of the refresh operation is set therein. The cell mode bits RTZ0-3 are provided corresponding to the memory blocks BLK0-3, respectively, and cell mode information indicating the single-cell mode or the twin-cell mode is set therein.

When a logic 0 is set in the refresh mode bits RFFZ0-3, the refresh operations of the corresponding memory blocks BLK0-3 are enabled, and when a logic 1 is set in the refresh mode bits RFFZ0-3, the refresh operations of the corresponding memory blocks BLK0-3 are disabled. When the logic 0 is set in the cell mode bits RTZ0-3, the corresponding memory blocks BLK0-3 operate in the single-cell mode, and when the logic 1 is set in the cell mode bits RTZ0-3, the corresponding memory blocks BLK0-3 operate in the twin-cell mode. Here, the single-cell mode is an operation mode in which data is retained in one memory cell MC, and the twin-cell mode is an operation mode in which complementary data is retained in a pair of memory cells MC.

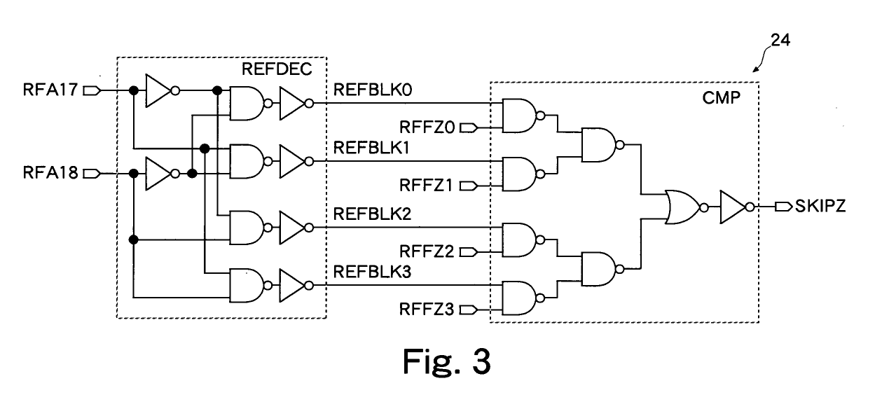

FIG. 3 shows details of the address comparison circuit 24 shown in FIG. 1. The address comparison circuit 24 includes a decoder REFDEC decoding the refresh address signal RFA17-18 and a comparator CMP comparing decoded signals REFBLK0-3 outputted from the decoder REFDEC and the refresh mode signals RFFZ0-3. The decoder REFDEC activates the decoded signal REFBLK0 indicating that the memory block BLK0 is to be refreshed to the high logic level, for example, when the value of the refresh address signal RFA17-18 is “00”. Namely, the decoder REFDEC activates any of the decoded signals REFBLK0-3 to the high logic level according to the value of the refresh address signal RFA17-18.

The comparator CMP activates the skip signal SKIPZ when the refresh mode signal RFFZ (any of RFFZ0-3) corresponding to the high logic level decoded signal REFBLK (any of REFBLK0-3) is at the high logic level. Namely, when the memory block BLK indicated by the refresh address signal RFA10-18 matches the memory block BLK corresponding to the refresh mode bit RFFZ (=1) in which the disable of the refresh operation is set, the skip signal SKIPZ is activated. When the memory block BLK indicated by the refresh address signal RFA10-18 matches the memory block BLK corresponding to the refresh mode bit RFFZ (=0) in which the refresh operation is enabled, the skip signal SKIPZ is inactivated.

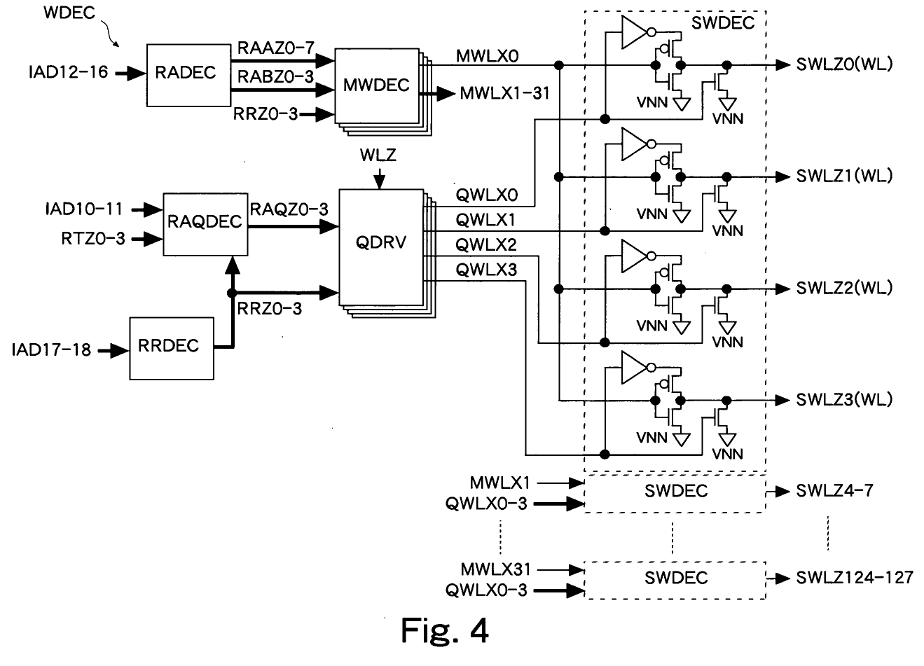

FIG. 4 shows details of the word decoder WDEC shown in FIG. 1. The word decoder WDEC includes a predecoder RADEC, main word decoders MWDEC, a block decoder RRDEC, a quarter decoder RAQDEC, quarter drivers QDRV, and sub-word decoders SWDEC. The word decoder WDEC operates in synchronization with the row timing signal RASZ outputted from the core control circuit 28 in FIG. 1.

To select a main word line MWLX0-31, the predecoder RADEC activates a decoded signal RAAZ (any of RAAZ0-7) corresponding to the value of an internal row address signal IAD12-14 and a decoded signal RABZ (any of RABZ0-3) corresponding to the value of an internal row address signal IAD15-16 to the high logic level. The predecoder RADEC is formed in common to the memory blocks BLK0-3. The main word decoder MWDEC activates any of the main word lines MWLX0-31 to the low logic level according to the decoded signals RAAZ0-7, RABZ0-3. The main word decoder MWD is formed for each memory block BLK0-3.

To select the memory block BLK0-3 in which the access operation and the refresh operation are performed, the block decoder RRDEC activates a block decoding signal RRZ (any of RRZ0-3) corresponding to the value of the internal row address signal IAD17-18 to the high logic level. The block decoding signals RRZ0-3 are signals to select the memory blocks BLK0-3, respectively. The block decoder RRDEC is formed in common to the memory blocks BLK0-3.

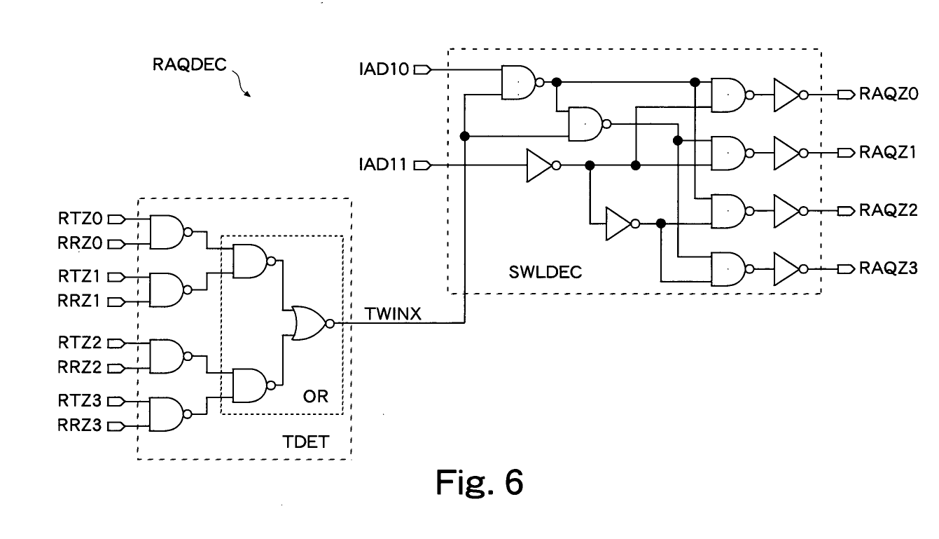

To select a sub-word line SWLZ (word line WL), the quarter decoder RAQDEC activates a decoded signal RAQZ (any of RAQZ0-3) corresponding to the value of an internal row address signal IAD10-11 to the high logic level. Note, however, that the quarter decoder RAQDEC activates a pair of decoded signals RAQ (RAQZ0-1 or RAQZ2-3) to the high logic level when the access operation or the refresh operation is performed in the memory block BLK set to the twin-cell mode. Namely, when the cell mode signal RTZ0-3 is at a high logic level, the quarter decoder RAQDEC judges that the twin-cell mode is set. The quarter decoder RAQDEC is formed in common to the memory blocks BLK0-3. Details of the quarter decoder RAQDEC will be described in FIG. 6.

The quarter driver QDRV activates a sub-word activation signal QWLX0-3 corresponding to the activated decoded signal RAQZ0-3 to the low logic level in synchronization with the word line activation signal WLZ. When the memory block BLK set to the single-cell mode is accessed, any of the word activation signals QWLX0-3 is activated. When the memory block BLK set to the twin-cell mode is accessed, any pair of the word activation signals QWLX0-1, QWLX2-3 is activated. The quarter driver QDRV is formed for each memory block BLK0-3. Details of the quarter driver QDRV will be described in FIG. 6.

The sub-word decoder SWDEC is formed for each main word line MWLX0-31. The sub-word decoder SWD which receives the main word line MWLX activated to the low logic level activates the sub-word line SWLZ (one or two of SWLZ0-127) corresponding to the word activation signal QWLX0-3 activated to the low logic level to the high logic level. For example, the high logic level of the sub-word line SWLZ is a boost voltage VPP, and the low logic level of the sub-word line SWLZ is a negative voltage VNN.

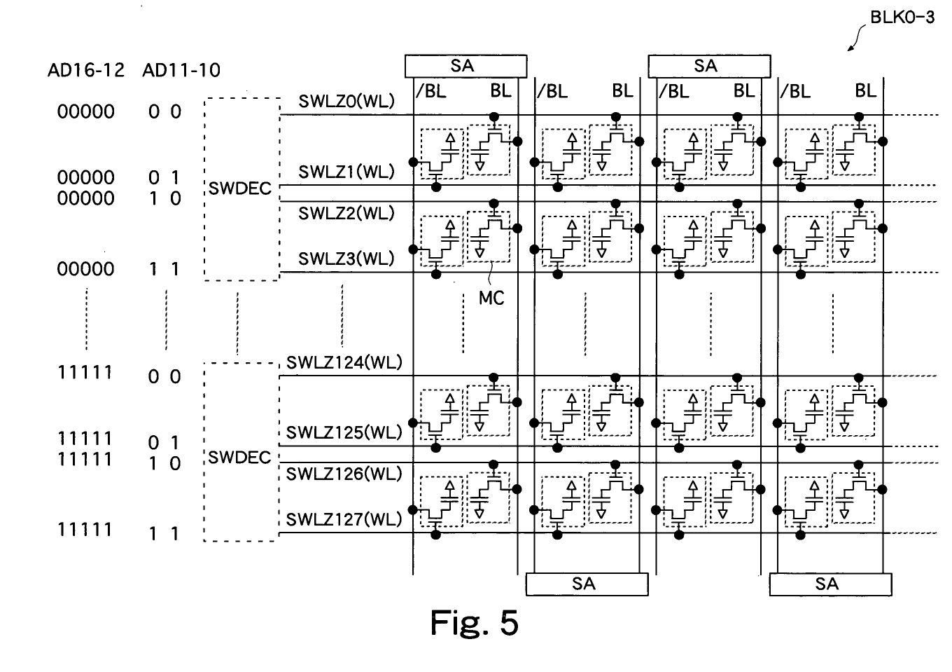

FIG. 5 shows details of the memory block BLK0-3 shown in FIG. 1. The internal row address signal IAD10-16 is allocated to the word line WL (sub-word line SWLZ0-127). The memory cells MC connected to one word line WL (sub-word line SWLZ0-127) are each connected to any of complementary bit lines BL, /BL. Each bit line pair BL, /BL is connected to the sense amplifier SA. When the memory cell MC connected to one of the bit line pair BL, /BL is accessed, the other of the bit line pair BL, /BL functions as a reference bit line.

FIG. 6 shows details of the quarter decoder RAQDEC shown in FIG. 4. The quarter decoder RAQDEC includes a twin detecting circuit TDET and a decoding circuit SWLDEC.

The twin detecting circuit TDET includes four NAND gates which each detect that both the cell mode signal RTZ (any of RTZ0-3) and the block decoding signal RRZ (any of RRZ0-3) are at the high logic level and an OR circuit connected to outputs of the NAND gates. The twin detecting circuit TDET activates a twin-cell mode signal TWINX when detecting that the memory block BLK0-3 corresponding to the cell mode bit RTZ0-3 in which the twin-cell mode is set is accessed.

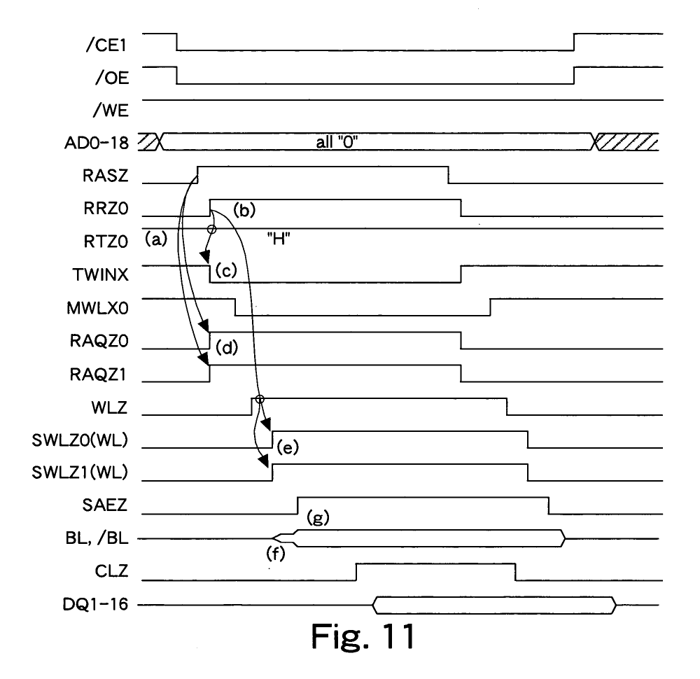

The decoding circuit SWLDEC activates any of the decoded signals RAQZ0-3 to select the word line WL according to the row address signal IAD10-11. Note, however, that the decoding circuit SWLDEC makes a decoding logic of the internal row address signal IAD10 (least significant bit of the row address signal IAD10-18) invalid when the twin-cell mode signal TWINX is activated. Thus, as shown in FIG. 11 described later, when the twin-cell mode signal TWINX is activated, the read operation RD, the write operation WR, and the refresh operation are performed by selecting a pair of word lines WL.

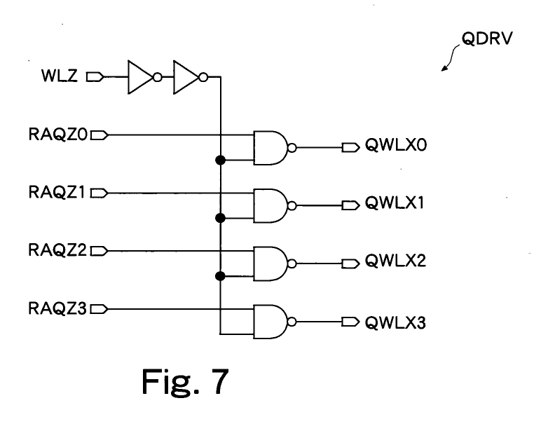

FIG. 7 shows details of the quarter driver QRDV shown in FIG. 4. The quarter driver QRDV includes NAND gates which receive the decoded signals RAQZ0-3, respectively. The NAND gates activate the word activation signals QWLX0-3 to the low logic level in synchronization with the word line activation signal WLZ when the decoded signals RAQZ0-3 are activated to the high logic level.

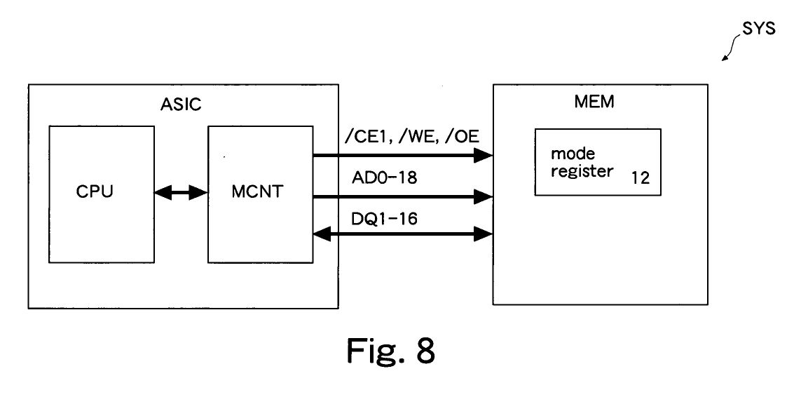

FIG. 8 shows a system SYS on which the memory MEM shown in FIG. 1 is mounted. The system SYS includes, for example, the memory chip MEM and an ASIC (logic chip) which accesses the memory chip MEM, and it is formed as a system in package SIP. The ASIC includes for example, a CPU and a memory controller MCNT.

To access the memory MEM, the memory controller MCNT outputs the access command (/CE1, /WE, /OE), the address signal AD0-18, and the write data DQ1-16 and receives the read data DQ1-16 from the memory MEM. Further, to set the mode register 12, the memory controller MCNT outputs the access command (/CE1, /WE, /OE) and the address signal AD0-18 and sets the operation modes of the blocks BLK0-3 of the memory MEM. The uses (reliability of data required by the system) of the memory blocks BLK0-3 change according to the status of the system SYS. The memory controller MCNT dynamically changes the operation modes of the memory blocks BLK0-3 according to their uses.

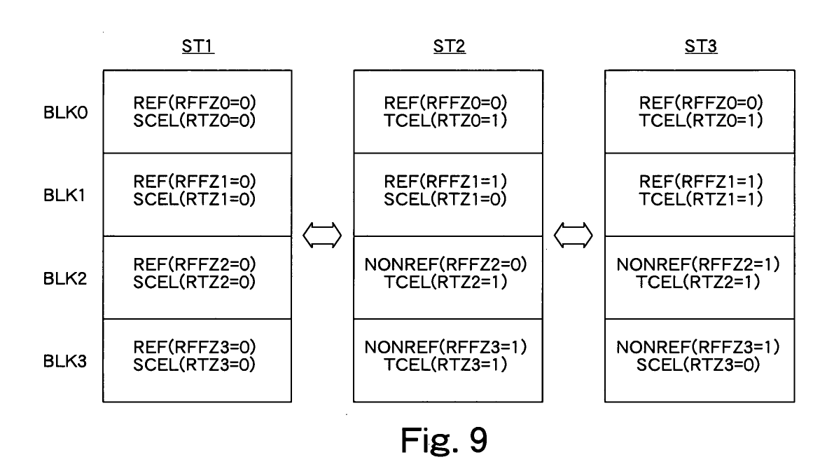

FIG. 9 shows an example in which the operation mode of the memory MEM shown in FIG. 1 is changed. FIG. 9 is also applied to a second embodiment described later. First, in a state ST1, the refresh mode bits RFFZ0-3 and the cell mode bits RTZ0-3 are all set to the logic 0. Therefore, the memory blocks BLK0-3 operate as refresh blocks REF in which the refresh operation is regularly performed, and perform the read operation RD, the write operation WR, and the refresh operation REF in a single-cell mode SCEL.

If the mode register set command MRS is supplied during the state ST1, the refresh mode bits RFFZ1, 2 are changed to the logic 1, and the cell mode bits RTZ0, 2-3 are changed to the logic 1, in synchronization with this change, the memory MEM transits to a state ST2. In the state ST2, the memory blocks BLK0, 2 operate as the refresh blocks REF in which the refresh operation is regularly performed. The memory blocks BLK1, 3 operate as non-refresh blocks NONREF in which the refresh operation is disabled.

The non-refresh block NONREF is set when a data retention time (for example, 10 ms) is shorter than a data retention time (for example, 50 ms) of the dynamic memory cell when the refresh operation is not performed. More specifically, the memory block BLK1 is used in the state ST1 to store data whose data retention time is 50 ms or more. When the operating state of the system SYS changes and the data retention time becomes less than 50 ms, the memory controller MCNT rewrites the value of the mode register 12 to shift the operating state of the memory MEM from the state ST1 to the state ST2. Consequently, the refresh operation in the memory block BLK1 is not performed, thereby reducing the power consumption of the memory MEM. The same goes for the memory block BLK3.

Further, in the state ST2, the memory blocks BLK0, 2-3 perform the read operation RD, the write operation WR, and the refresh operation REF in a twin-cell mode TCEL. The memory block BLK1 performs the read operation RD, the write operation WR, and the refresh operation REF in the single-cell mode SCEL. In the twin-cell mode TCEL, a one-bit data signal is retained in a pair of memory cells MC. An electric charge amount retained in a pair of memory cells MC is larger than an electric charge amount retained in one memory cell MC. Therefore, the reliability of data can be improved in the twin-cell mode TCEL compared to the single-cell mode SCEL. In other words, if the reliability of data needs to be raised, the memory block BLK in which the data is retained is set to the twin-cell mode TCEL.

The reliability of data retained in the memory cell is, in descending order, as follows: (1) twin-cell mode CEL+refresh enable; (2) single-cell mode SCEL+refresh enable; (3) twin-cell mode TCEL+refresh disable; (4) single-cell mode SCEL+refresh disable. Further, the power consumption is relatively high in the above (1), (2), and relatively low in the above (3), (4). Note, however, that in the present invention, during a normal operation mode, the memory block BLK in which the refresh operation is disabled can be set individually. Hence, the power consumption of the memory MEM can be always minimized in accordance with a specification of the system SYS. Moreover, by changing the operation modes of the memory blocks BLK0-3 in accordance with a change in the operating status of the system SYS, the power consumption of the memory MEM can be always minimized.

If the mode register set command MRS is supplied during the state ST2, the refresh mode bit RFFZ2 is changed to the logic 1, the cell mode bit RTZ1 is changed to the logic 1, and the cell mode bit RTZ3 is changed to the logic 0, in synchronization with this change, the memory MEM transits to a state ST3. In the state ST3, the memory block BLK0 operates as the refresh block REF in which the refresh operation is regularly performed. The memory blocks BLK1-3 operate as non-refresh blocks NONREF in which the refresh operation is disabled. The memory blocks BLK0-2 perform the read operation RD, the write operation WR, and the refresh operation REF in the twin-cell mode TCEL, and the memory block BLK3 performs the read operation RD, the write operation WR, and the refresh operation REF in the single-cell mode SCEL.

The state of the memory MEM is not limited to the above states ST1-3, and a combination of the refresh block REF, non-refresh block NONREF, single-cell mode SCEL, and twin-cell mode TCEL can be arbitrarily set for each memory block BLK0-3. Generally, the mode register 12 is set during the normal operation mode. Here, the normal operation mode is an operation mode in which the read operation RD, the write operation WR, and the refresh operation REF are performed in response to the access requests RD, WR, and the refresh request RREQ.

In the present invention, when the value of the mode register 12 is rewritten, the states of the respective memory blocks BLK0-3 are changed as shown in FIG. 9 while the normal operation mode remains maintained. Namely, the states of the respective memory blocks BLK0-3 are dynamically changeable. Further, a transition from the normal operation mode to a standby operation mode is made, the states of the respective memory blocks BLK0-3 are continued as they are. Namely, the uses (reliability of data required by the system) of the memory blocks BLK0-3 can be dynamically changed according to the status of the system SYS.

On the other hand, in a conventional semiconductor memory, when the memory block BLK in which the refresh operation is disabled is set, this setting becomes valid only in the standby operation mode (data retention mode) (partial refresh setting). Further, settings of the single-cell mode SCEL and the twin-cell mode TCEL become valid only in the standby operation mode.

Here, the normal operation mode is an operation mode which is set during a period when the chip enable signal /CE1 is activated to a low level and in which the read operation RD, the write operation WR, and the refresh operation REF are performed in response to the access requests RD, WR, and the refresh request RREQ. The standby operation mode is an operation mode which is set during a period when the chip enable signal /CE1 is inactivated to a high level and in which the acceptance of the access requests RD, WR is disabled. During the standby operation mode, only the refresh operation is performed.

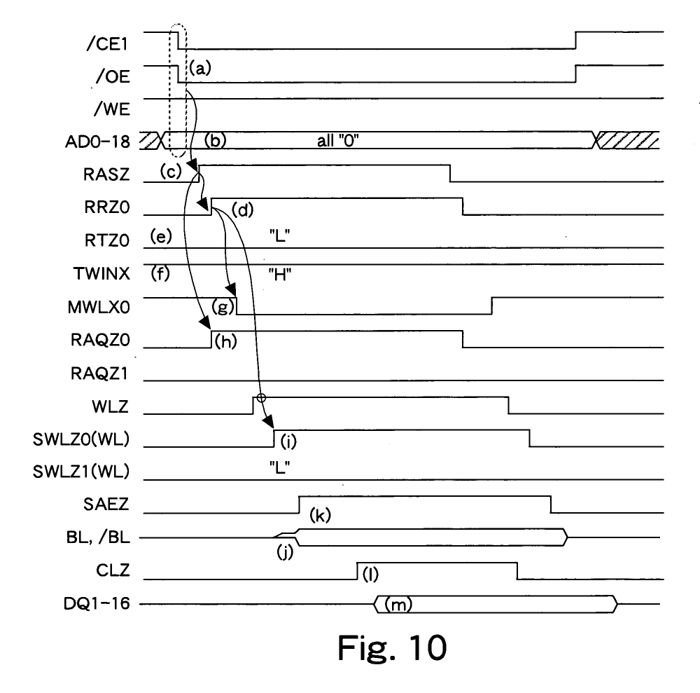

FIG. 10 shows a read operation of the memory block BLK set to the single-cell mode SCEL. In the read operation, the /CE1 signal and the /OE signal are activated to the low logic level, and the /WE signal is retained at the high logic level (FIG. 10(a)). Namely, the read command RD is supplied. In synchronization with the read command RD, the address signal AD0-18 (all logic 0s in this example) indicating the memory cell MC to be read-accessed is supplied (FIG. 10(b)). The value (“00”) of the address signal AD17-18 indicates the memory block BLK0. Therefore, the access operation of the memory block BLK0 is performed. The core control circuit 28 activates the row timing signal RASZ in synchronization with the read command RD (FIG. 10(c)).

The decoder RRDEC shown in FIG. 4 activates the decoded signal RRZ0 to access the memory block BLK0 according to the internal row address signal IAD17-18 (FIG. 10(d)). In this example, since the memory block BLK0 is set to the single-cell mode SCEL, the cell-mode signal RTZ0 is maintained at the low logic level (FIG. 10(e)). Therefore, the twin-cell mode signal TWINX shown in FIG. 6 is maintained at the high logic level (FIG. 10(f)). Namely, the read operation shown in FIG. 10 operates in the single-cell mode SCEL.

The main word decoder MWDEC shown in FIG. 4 activates the main word line MWLX0 according to the address signal AD12-16 (FIG. 10(g)). The quarter decoder RAQDEC activates the decoded signal RAQZ0 upon receiving the address signal AD10-11 and the high logic level twin-cell mode signal TWINX (FIG. 10(h)). Then, one sub-word line SWL0 (WL) is selected in synchronization with the word line activation signal WLZ (FIG. 10(i)).

In synchronization with the selection of the word line WL, the data signal is read from the memory cell MC to the bit line BL, and a voltage difference occurs between the bit line pair BL, /BL (FIG. 10(j)). Incidentally, when the sub-word line SWLZ ending with an odd number is selected, the data signal is read to the bit line /BL. Then, in synchronization with the sense amplifier activation signal SAEZ, the sense amplifier SA starts to operate and amplifies the voltage difference between the bit lines BL, /BL (FIG. 10(k)). After this, the column switch CSW selected by the address signal AD0-9 is turned on in synchronization with activation of the column control signal CLZ (FIG. 10(l)). The read data signal on the bit lines BL, /BL is amplified and latched by the read amplifier RA and outputted to the outside of the memory MEM via the data terminals DQ1-16 (FIG. 10(m)).

Incidentally, when the refresh operation is performed, the /CE1 signal, the /OE signal, and the /WE signal are inactivated, and the address signal AD0-18 are not supplied. Further, since the column control signal CLZ is inactivated, the data signal amplified by the sense amplifier SA is not outputted to the outside of the memory MEM and rewritten only into the memory cell MC. When the write operation is performed, the write enable signal /WE is activated to the low logic level, and the sense amplifier SA amplifies the write data signal DQ1-16 supplied via the data terminals DQ1-16. Further, to supply the write data signal to the bit lines BL, /BL quickly, the activation timing of the column selection signal CLZ becomes faster compared to the read operation. The other operations are the same as those of the read operation.

FIG. 11 shows a read operation of the memory block BLK set to the twin-cell mode TCEL. A detailed description of the same operation as in FIG. 10 is omitted. Incidentally, in this embodiment, when a change from the single-cell mode SCEL to the twin-cell mode TCEL is made, data retained in the memory cells MC during the single-cell mode are not guaranteed. Hence, after switching to the twin-cell mode TCEL, it is necessary to write data in each memory cell MC. In contrast, in the second embodiment described later, even in a state immediately after the change from the single-cell mode SCEL to the twin-cell mode TCEL, data retained in the memory cells MC during the single-cell mode SCEL are guaranteed.

Also in this example, the value of the address signal AD0-18 is constituted of all logic 0s. Therefore, the access operation of the memory block BLK0 is performed. The memory block BLK0 is set to the twin-cell mode TCEL. Hence, the cell mode signal RTZ0 outputted from the mode register 12 maintains the high logic level (FIG. 11(a))

The decoder RRDEC shown in FIG. 4 activates the decoded signal RRZ0 to access the memory block BLK0 in response to the internal row address signal IAD17-18 (FIG. 11(b)). Since both the decoded signal RRZ0 and the cell mode signal RTZ0 are at the high logic level, the twin detecting circuit TDET shown in FIG. 6 changes the twin-cell mode signal TWINX to the low logic level (FIG. 11(c)). The decoding circuit SWLDEC in the quarter decoder RAQDEC makes the decoding logic of the internal row address signal IAD10 invalid in response to the low logic level twin cell mode signal TWINX. Therefore, a pair of decoded signals RAQZ0-1 are simultaneously activated in response to the internal row address signal IAD11 (logic 0 in this example) (FIG. 11(d)). Then, a pair of sub-word lines SWLZ0-1 (WL) are simultaneously selected in synchronization with the word line activation signal WLZ (FIG. 11(e)).

As described above, the twin detecting circuit TDET can easily detect whether the memory cell MC is accessed in the twin-cell mode TCEL or accessed in the single-cell mode SCEL in each memory block BLK0-3. In other words, even when the memory block BLK0-3 is randomly accessed, the cell mode can be switched at every access to the memory block BLK0-3 by a simple circuit.

In synchronization with the selection of the pair of word lines WL, complementary data signals are read from a pair of memory cells MC to the bit lines BL, /BL, and a voltage difference occurs between the bit line pair BL, /BL (FIG. 11(f)). Then, in synchronization with the sense amplifier activation signal SAEZ, the sense amplifier SA starts to operate and amplifies the voltage difference between the bit lines BL, /BL (FIG. 11(g)). Operations after this are the same as those in FIG. 10. Operational waveforms of the refresh operation and the write operation are the same as those of the contents described in FIG. 10.

Incidentally, in the twin-cell mode TCEL, to store complementary data signals to a pair of memory cells MC connected to complementary bit lines BL, /BL, the electric charge amount retained in the pair of memory cells becomes twice as much as that in the single-cell mode SCEL. Hence, the intervals between the refresh operations of each memory cell MC can be made longer compared to the single-cell mode SCEL. Accordingly, by making the generation cycle of the refresh request signal RREQZ during the twin-cell mode TCEL longer compared to the single-cell mode SCEL, the power consumption can be further reduced.

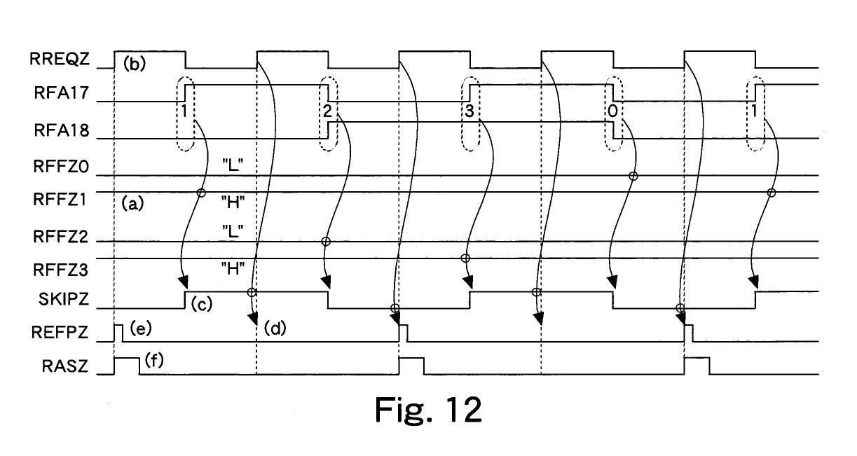

FIG. 12 shows a refresh operation according to set values of the refresh mode bits RFFZ0-3. This example shows an operation when the operation mode of the memory MEM is set to the state ST2 shown in FIG. 9. The refresh mode bits RFFZ0-3 retain the logic 0, the logic 1, the logic 0, and the logic 1, respectively (FIG. 12(a)).

The refresh timer 18 shown in FIG. 1 periodically outputs the refresh request signal RREQZ (FIG. 12(b)). The refresh request signal RREQZ is, for example, an oscillation signal whose high logic level and low logic level periods are almost equal. The refresh address counter 20 updates the refresh address signal RFA10-18 in synchronization with a falling edge of the refresh request signal RREQZ. To sequentially perform the refresh operation on the memory blocks BLK0-3, the refresh address counter 20 allocates two bits RFA17-18 to select the memory block 0-3 to low-order bits of the counter. Therefore, in synchronization with the falling edge of the refresh request signal RREQZ, the value of the refresh address signal RFA17-18 increases to “1”, “2”, “3”, “0”, “1” in sequence.

Incidentally, to intensively perform the refresh operation in each memory block BLK0-3, the bits RFA17-18 may be allocated to high-order bits of the refresh address counter. In this case, the value of the refresh address counter is sequentially updated from low-order bits (such as RFA10-11) of the refresh address signal RFA10-18 in synchronization with the falling edge of the refresh request signal RREQZ. Namely, the refresh operation of the same memory block BLK is continuously performed.

The address comparison circuit 24 shown in FIG. 1 activates the skip signal SKIPZ while the refresh address signal RFA17-18 indicating the memory blocks BLK1, 3 corresponding to the high logic level refresh mode bits REFZ1, 3 is outputted (FIG. 12(c)). While the skip signal SKIPZ is activated, the refresh control circuit 26 disables acceptance of the refresh request signal RREQZ and masks the output of the refresh request signal REFPZ (FIG. 12(d)). Thus, the refresh operation of the memory block BLK whose corresponding refresh mode bit REFZ is set to “1” is not performed.

On the other hand, while the skip signal SKIPZ is inactivated, the refresh control circuit 26 outputs the refresh request signal REFPZ in synchronization with the refresh request signal RREQZ (FIG. 12(e)). Namely, the supply of the refresh request signal REFPZ to the core control circuit 28 is enabled. The core control circuit 28 activates the row timing signal RASZ in response to the refresh request signal RREPZ to perform the refresh operation (FIG. 12(f)). As just described, by comparing the refresh address signal RFA17-18 and the refresh mode bit RFFZ0-3 by the address comparison circuit 24 and inactivating/activating the skip signal SKIPZ, the enable/disable of the refresh operation can be controlled in each block BLK0-3 by a simple circuit.

As described above, in the first embodiment, the semiconductor memory MEM can be operated optimally according to the specification of the system SYS, enabling a reduction in power consumption. In particular, even when the status of the system SYS changes and the uses of the memory blocks BLK0-3 and the reliability of data required by the system SYS are changed, the operation modes of the memory blocks BLK0-3 can be independently and dynamically changed in accordance with the change of the status. For example, by operating only the memory block BLK requiring high reliability in the twin-cell mode TCEL, the memory capacity of the memory MEM can be minimized. As a result, the memory MEM with a small memory capacity can be adopted, which can prevent an increase in power consumption. Further, when only a short retention time of data in the memory cell MC is required, the power consumption can be reduced by disabling the refresh operation of the corresponding memory block BLK.

In the pseudo SRAM such as the FCRAM, no refresh request is supplied from outside. On the other hand, the refresh request signal RREQZ is periodically generated from the refresh timer 18 regardless of the normal operation mode or the standby operation mode. Therefore, by monitoring partial bits (RFA17-18) of the refresh address signal RFA by the simple circuit such as the address comparison circuit 24, the enable/disable of the refresh operation can be controlled in each memory block BLK0-3. In contrast, when the refresh request is supplied from outside, it is necessary to detect a refresh command and a refresh address to control the enable/disable of the refresh operation, and thereby the circuit becomes complicated. In particular, in a semiconductor memory which can perform the refresh operation according to an external refresh request and an internal refresh request (self-refresh request), the circuit for controlling the enable/disable of the refresh operation becomes complicated.

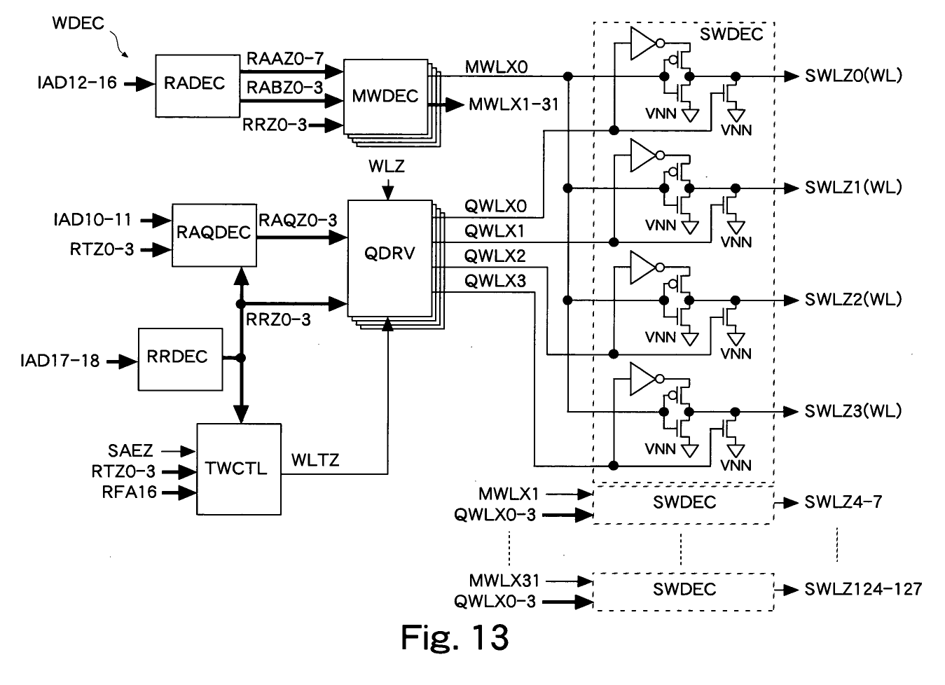

FIG. 13 shows details of the word decoder WDEC in the second embodiment of the present invention. The same reference symbols are used to designate the same elements as those described in the first embodiment, and a detailed description thereof is omitted. The word decoder WDEC is constituted by adding a twin control circuit TWCTL to the word decoder WDEC of the first embodiment. Further, the circuit configuration of the quarter driver QDRV differs from that of the first embodiment. The other constitutions of the semiconductor memory MEM are the same as that those of the first embodiment (FIG. 1-FIG. 6). Note that, as in FIG. 8 described above, the system SYS is constituted of the memory chip MEM and the ASIC accessing the memory chip MEM.

When the operation mode is changed from the single-cell mode SCEL to the twin-cell mode TCEL in each memory block BLK0-3, the twin control circuit TWCTL activates a word line activation signal WLTZ whose timing is different from that of the word line activation signal WLZ until access to all memory cells is finished. The quarter driver QDRV sequentially activates the sub-word activation signals QWLX0-1 (or QWLX2-3) in synchronization with the word line activation signals WLZ, WLTZ, respectively. The word decoder WDEC including the twin control circuit TWCTL and the core control circuit 28 shown in FIG. 1 function as an access control unit which performs the access operation and the refresh operation on the memory block BLK0-3 in response to the access request RD, WR and the refresh request RREQZ and also operates each memory block BLK in the single-cell mode SCEL, the twin-cell mode TCEL, or a transitional twin-cell mode according to the cell mode signals RTZ0-3 (cell mode information) outputted from the mode register 12.

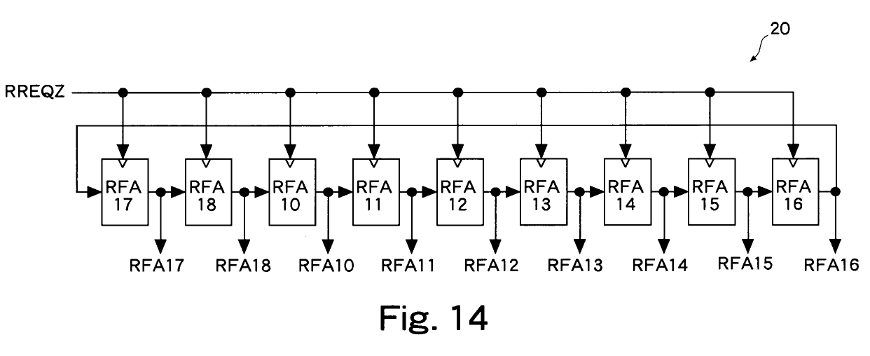

FIG. 14 shows details of the refresh address counter 20 (FIG. 1). The refresh address counter 20 includes memory stages corresponding to respective bits of the refresh address signal RFA10-18, and a final-stage output is fed back to an initial stage. The memory stages correspond to bits RFA17, RFA18, RFA10-16 from the least significant side. RAF17 as the least significant bit is inverted with respect to each refresh request signal RREQZ.

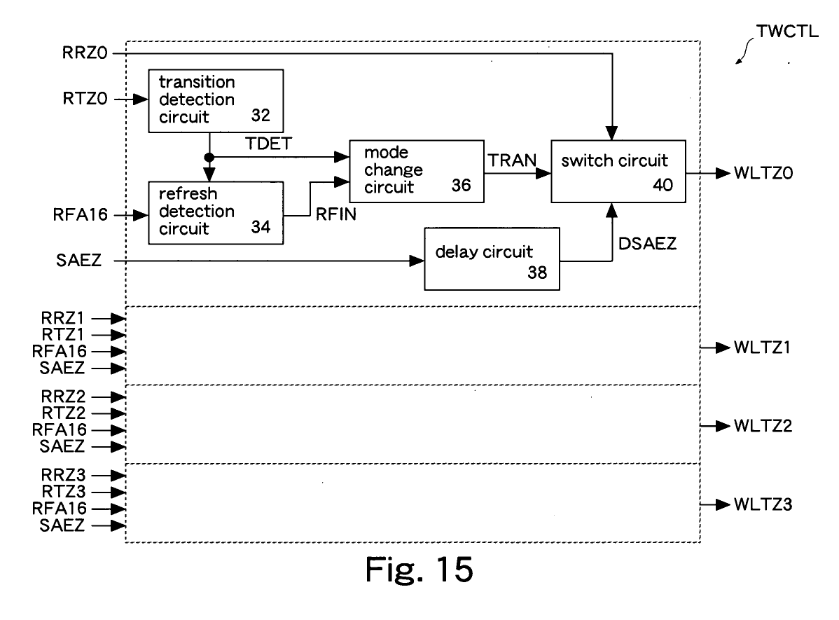

FIG. 15 shows details of the twin control circuit TWCTL shown in FIG. 13. The twin control circuit TWCTL includes a transition detection circuit 32, a refresh detection circuit 34 (access detection circuit), a mode change circuit 36, a delay circuit 38, and a switching circuit 40 for each memory block BLK0-3. Incidentally, the delay circuit 38 may be formed in common to four switching circuits 40. The twin control circuit TWCTL has the same circuit configuration for each memory block BLK0-3, and hence here the circuit corresponding to the memory block BLK0 will be described.

When the cell mode signal RTZ0 changes from the low logic level to the high logic level, that is, the memory block BLK0 is changed from the single-cell mode SCEL to the twin-cell mode TCEL, the transition detection circuit 32 temporarily activates a transition detection signal TDET (pulse signal).

When detecting three rising edges of a refresh address signal RFA16 after receiving the activation of the transition detection signal TDET, the refresh detection circuit 34 temporarily activates a refresh finish signal RFIN (access finish signal; pulse signal).

The refresh address signal RFA16 being the most significant bit of the refresh address counter 20 is set to the low logic level and the high logic level, respectively, during a half period of a period when the counter value of the refresh address counter 20 returns to its initial value. Therefore, it can be detected by detecting two rising edges (or falling edges) of the refresh address signal RFA16 that the counter value returns to its initial value. Note, however, that as shown in FIG. 12, there is a time lag from when the refresh address signal RFA10-18 is updated and the refresh request signal RREQZ is outputted until the refresh operation is performed. Hence, it can be certainly detected by detecting three rising edges (or falling edges) of the refresh address signal RFA16 that the refresh operation has been performed on all of the memory cells MC (word lines WL) in the memory block BLK0.

The mode change circuit 36 activates a transitional signal TRANZ in response to the activation of the transition detection signal TDET, and inactivates the transitional signal TRANZ in response to the activation of the refresh finish signal RFIN. A period for which the transitional signal TRANZ is activated is a period indicating the transitional twin-cell mode. The transitional twin-cell mode is an operation mode to retain data retained in one of a pair of memory cells as complementary data in the pair of memory cells MC by starting access to one of the pair of memory cells MC and then starting access to the other of the pair of memory cells MC. Regarding respective memory cells MC, one-bit data is stored by a pair of memory cells MC by performing the access operation (including the refresh operation) in the transitional twin-cell mode. Hence, after the transitional signal TRANZ is inactivated, the operation in the twin-cell mode TCEL becomes possible. As just described, the mode change circuit 36 changes the operation mode of the corresponding memory block BLK0 from the single-cell mode SCEL to the transitional twin-cell mode in response to the transition detection signal TDET, and changes the operation mode of the corresponding memory block BLK0 from the transitional twin-cell mode to the twin-cell mode TCEL in response to the refresh finish signal RFIN.

The delay circuit 38 outputs a delay signal DSAEZ obtained by delaying the sense amplifier activation signal SAEZ. The switching circuit 40 activates the word line activation signal WLTZ in synchronization with the delay signal DSAEZ when the block decoding signal RRZ0 is activated during a period when the transitional signal TRANZ is activated (transitional twin-cell mode). The block decoding signal RRZ0 indicates that the memory block BLK0 is accessed. The switching circuit 40 outputs the high logic level word line activation signal WLTZ during a period when the transitional signal TRANZ is inactivated (single-cell mode SCEL and the twin-cell mode TCEL).

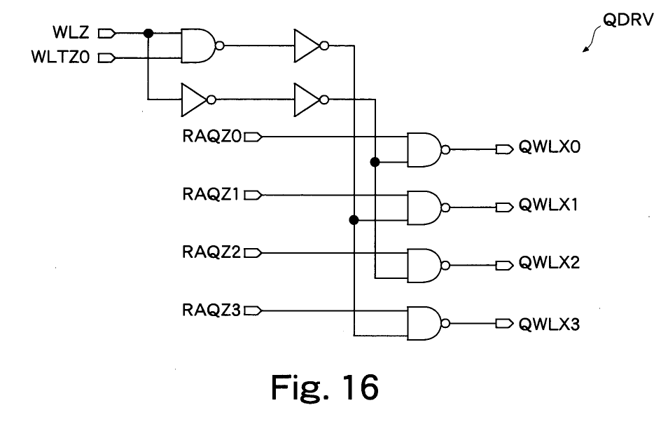

FIG. 16 shows the quarter driver QDRV shown in FIG. 13. The quarter driver QRDV in FIG. 16 corresponds to the memory block BLK0. The quarter drivers QRDV of the memory blocks BLK1-3 are constituted by supplying word line activation signals WLTZ1-3 instead of the word line activation signal WLTZ0.

In the quarter driver QRDV, one inputs of NAND gates which output the sub-word activation signals QWLX0, 2 receive the word line activation signal WLZ. One inputs of NAND gates which output the sub-word activation signals QWLX1, 3 receive an AND logic signal of the word line activation signals WLZ, WLTZ0. Thus, in the single-cell mode SCEL and the twin cell mode TCEL in which the word line activation signal WLTZ1 is retained at the high logic level, the sub-word activation signals QWLX0-3 are activated in synchronization with the word line activation signal WLZ. In the transitional twin-cell mode in which the word line activation signal WLTZ1 changes from the low logic level to the high logic level, the sub-word activation signal QWLX1 (or QWLX3) is activated behind the activation of the sub-word activation signal QWLX0 (or QWLX2).

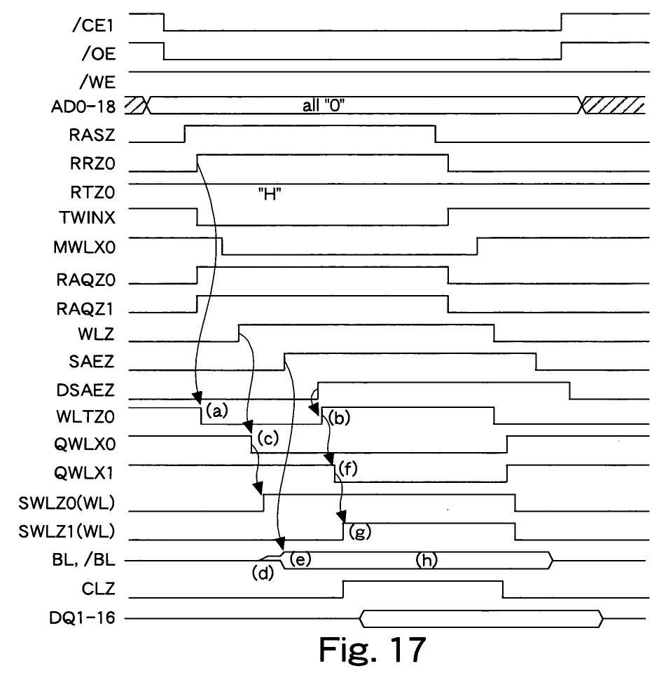

FIG. 17 shows a read operation in the transitional twin-cell mode in the second embodiment. Incidentally, the operation in the single-cell mode SCEL and the operation in the twin-cell mode TCEL are the same as those in FIG. 10 and FIG. 11 described above. A detailed description of the same operations as in FIG. 10 and FIG. 11 is omitted. For example, the address signal AD0-18 is constituted of all logic 0s. Therefore, the access operation of the memory block BLK0 is performed. During the transitional twin-cell mode, the cell-mode signal RTZ0 maintains the high logic level. Hence, the waveforms of the decoded signals RAQZ0-1 are the same as those in FIG. 11.

The word line activation signal WLTZ0 is inactivated in synchronization with the activation of the decoded signal RRZ0 (FIG. 17(a)), and activated in synchronization with the activation of the delay signal DSAEZ obtained by delaying the sense amplifier activation signal SAEZ (FIG. 17(b)). The sub-word activation signal QWLX0 is activated in synchronization with the activation of the word line activation signal WLZ (FIG. 17(c)). The sub-word line SWL0 is activated in synchronization with the activation of the sub-word activation signal QWLX0. In synchronization with the activation of the sub-word line SWLZ0, the data signal is read from the memory cell MC connected to the sub-word line SWLZ0 to the bit line BL, and a voltage difference occurs between the bit line pair BL, /BL (FIG. 17(d)). The sense amplifier SA amplifiers the voltage difference between the bit lines BL, /BL in synchronization with the sense amplifier activation signal SAEZ (FIG. 17(e)). Thus, data retained in the memory cell MC connected to the bit line BL is read.

After the read data signal is fully amplified by the sense amplifier SA, the sub-word activation signal QWLX1 is activated in synchronization with the activation of the word line activation signal WLTZ0 (FIG. 17(f)). The sub-word line SWLZ1 is activated in synchronization with the activation of the sub-word activation signal QWLX1 (FIG. 17(g)). In synchronization with the activation of the sub-word line SWLZ1, the bit line /BL is connected to the memory cell MC, and complementary read data signals amplified by the sense amplifier SA are respectively written into the pair of memory cells MC connected to the bit lines BL, /BL (FIG. 17(h)). At this time, since the data signals on the bit lines BL, /BL are fully amplified by the sense amplifier SA, they are not influenced by the data signal read to the bit line /BL from the memory cell MC. Operational waveforms of the refresh operation and the write operation are the same as those of the contents described in FIG. 10.

As described above, also in the second embodiment, the same effect as in the above first embodiment can be obtained. Further, in this embodiment, by inserting the transitional twin-cell mode when the change from the single-cell mode SCEL to the twin-cell mode TCEL is made, data retained in the memory cells MC during the single-cell mode SCEL can be retained as they are. Accordingly, even when the cell mode bits RTZ0-3 in the mode register 12 are rewritten and thereby the cell mode is changed during the normal operation mode, data written during the single-cell mode SCEL can be guaranteed. Consequently, the usability of the memory MEM can be improved.

Moreover, the refresh detection circuit 34 can detect a finish timing of the transitional twin-cell mode by monitoring one bit (RFA16) of the refresh address signal RFA. This can reduce the circuit scale of the refresh detection circuit 34, which can reduce the chip size of the memory MEM. This results in a reduction in the costs of the memory MEM and the system SYS.

Incidentally, in the above embodiments, the example in which the present invention is applied to the pseudo SRAM (FCRAM) is described. The present invention is not limited to these embodiments. For example, the present invention may be applied to a clock synchronous type semiconductor memory such as a DRAM or an SDRAM.

In the above embodiments, the example in which it is detected by monitoring the refresh address signal RFA16 generated by the refresh address counter 20 that in each memory block BLK0-3, the refresh operation of all the memory cells MC has been performed is described. The present invention is not limited to these embodiments. For example, it may be detected by monitoring all bits of the refresh address signal RFA10-18 that the refresh operation of all the memory cells MC has been performed. In this case, the period of the transitional twin-cell mode can be shortened. Further, it may be detected by monitoring the row address signal AD10-18 supplied corresponding to the access request RD, WR together with the refresh address signal RFA10-18 that the refresh operation of all the memory cells MC has been performed. In this case, the period of the transitional twin-cell mode can be further shortened. As just described, if each memory cell MC is accessed at least once during the transitional twin-cell mode, a shift to the twin-cell mode can be made.

The many features and advantages of the embodiments are apparent from the detailed specification and, thus, it is intended by the appended claims to cover all such features and advantages of the embodiments that fall within the true spirit and scope thereof. Further, since numerous modifications and changes will readily occur to those skilled in the art, it is not desired to limit the inventive embodiments to the exact construction and operation illustrated and described, and accordingly all suitable modifications and equivalents may be resorted to, falling within the scope thereof.

What is claimed is:

1. A semiconductor memory, comprising:
plural memory blocks including dynamic memory cells;
a mode setting unit including a refresh mode part in which refresh mode information indicating enable/disable of a refresh operation is set for each of the memory blocks and a cell mode part in which cell mode information indicating a single-cell mode or a twin-cell mode is set for each of the memory blocks;
an access control unit performing an access operation and a refresh operation of the memory block in response to an access request and a refresh request and operating the respective memory blocks in the single cell mode or the twin-cell mode according to the cell mode information set in the cell mode part; and
a refresh control unit disabling the refresh request of the memory block corresponding to the refresh mode part in which the disable is set from being supplied to the access control unit, wherein
the single-cell mode is an operation mode in which data is retained in one memory cell, and
the twin-cell mode is an operation mode in which complementary data is retained in a pair of memory cells.

2. The semiconductor memory according to claim 1, further comprising:
a normal operation mode in which the access operation and the refresh operation are performed in response to the access request and the refresh request; and
a standby operation mode in which only the refresh operation is performed, wherein
in response to a change in the mode setting unit, the access control unit and the refresh control unit operate in accordance with changed information while maintaining an operation mode.

3. The semiconductor memory according to claim 1, further comprising:
complementary bit lines respectively connected to the pair of memory cells; and
a pair of word lines respectively connected to the pair of memory cells, wherein
the access control unit includes a word decoder selecting the word line according to a row address supplied corresponding to an access command, and
the word decoder selects one of the word lines according to the row address when the memory block corresponding to the cell mode part in which the single-cell mode is set is accessed, and selects the pair of word lines when the memory block corresponding to the cell mode part in which the twin-cell mode is set is accessed.

4. The semiconductor memory according to claim 3, wherein the word decoder comprises:
a twin detecting circuit activating a twin-cell mode signal when detecting that the memory block corresponding to the cell mode part in which the twin-cell mode is set is accessed; and
a decoding circuit generating a decoded signal to select each of the word lines according to the row address and making a decoding logic of a least significant bit of the row address invalid when the twin-cell mode signal is activated.

5. The semiconductor memory according to claim 1, wherein the refresh control unit comprises:
a refresh address counter sequentially generating a refresh address indicating the memory block and the memory cell on which the refresh operation is performed in response to the refresh request; and
a refresh control circuit disabling the supply of the refresh request to the access control unit when the memory block indicated by the refresh address matches the memory block corresponding to the refresh mode part in which the disable is set, and enabling the supply of the refresh request to the access control unit when the memory block indicated by the refresh address matches the memory block corresponding to the refresh mode part in which the enable is set.

6. The semiconductor memory according to claim 1, wherein
when the cell mode information in the cell mode part is changed to information indicating the twin-cell mode from that indicating the single-cell mode, the access control unit operates the corresponding memory block in the twin-cell mode after operating it in a transitional twin-cell mode until all of the memory cells in the corresponding memory block are accessed, and
the transitional twin-cell mode is an operation mode to retain data retained in one of the pair of memory cells as the complementary data in the pair of memory cells by starting access to one of the pair of memory cells and then starting access to other of the pair of memory cells.

7. The semiconductor memory according to claim 6, wherein the access control unit comprises:
a transition detection circuit activating a transition detection signal in each of the memory blocks when the cell mode information in the cell mode part is changed to information indicating the twin-cell mode from that indicating the single-cell mode;
an access detection circuit outputting an access finish signal when all of the memory cells in the corresponding memory block are accessed after the activation of the transition detection signal; and
a mode change circuit changing the operation mode of the corresponding memory block from the single cell mode to the transitional twin-cell mode in response to the transition detection signal and changing the operation mode of the corresponding memory block from the transitional twin-cell mode to the twin-cell mode in response to the access finish signal.

8. The semiconductor memory according to claim 7, wherein
the refresh control unit includes a refresh address counter sequentially generating a refresh address indicating the memory block and the memory cell on which the refresh operation is performed in response to the refresh request, and
the access detection circuit detects that all of the memory cells in the corresponding memory block are accessed by monitoring the refresh address generated by the refresh address counter.

9. The semiconductor memory according to claim 1, further comprising
a refresh request generation circuit periodically generating the refresh request, wherein
the refresh control circuit performs the refresh operation in response to only the refresh request generated by the refresh request generation circuit.

10. A system comprising a semiconductor memory and a controller accessing to the semiconductor memory, wherein the semiconductor memory comprises:
plural memory blocks including dynamic memory cells;
a mode setting unit including a refresh mode part in which refresh mode information indicating enable/disable of a refresh operation is set for each of the memory blocks and a cell mode part in which cell mode information indicating a single-cell mode or a twin-cell mode is set for each of the memory blocks;
an access control unit performing an access operation and a refresh operation of the memory block in response to an access request and a refresh request and operating the respective memory blocks in the single cell mode or the twin-cell mode according to the cell mode information set in the cell mode part; and
a refresh control unit disabling the refresh request of the memory block corresponding to the refresh mode part in which the disable is set from being supplied to the access control unit, wherein
the controller sets the refresh mode information and the cell mode information in the mode setting unit and controls the access to the semiconductor memory,
the single-cell mode is an operation mode in which data is retained in one memory cell, and
the twin-cell mode is an operation mode in which complementary data is retained in a pair of memory cells.

11. The system according to claim 10, wherein the semiconductor memory further comprises:
a normal operation mode in which the access operation and the refresh operation are performed in response to the access request and the refresh request; and
a standby operation mode in which only the refresh operation is performed, wherein
in response to a change in the mode setting unit, the access control unit and the refresh control unit operate in accordance with changed information while maintaining an operation mode.

12. The system according to claim 10, wherein the semiconductor memory comprises:
complementary bit lines respectively connected to the pair of memory cells; and
a pair of word lines respectively connected to the pair of memory cells, wherein
the access control unit includes a word decoder selecting the word line according to a row address supplied corresponding to an access command, and
the word decoder selects one of the word lines according to the row address when the memory block corresponding to the cell mode part in which the single-cell mode is set is accessed, and selects the pair of word lines when the memory block corresponding to the cell mode part in which the twin-cell mode is set is accessed.

13. The system according to claim 12, wherein the word decoder comprises:
a twin detecting circuit activating a twin-cell mode signal when detecting that the memory block corresponding to the cell mode part in which the twin-cell mode is set is accessed; and
a decoding circuit generating a decoded signal to select each of the word lines according to the row address and making a decoding logic of a least significant bit of the row address invalid when the twin-cell mode signal is activated.

14. The system according to claim 10, wherein the refresh control unit comprises:
a refresh address counter sequentially generating a refresh address indicating the memory block and the memory cell on which the refresh operation is performed in response to the refresh request; and
a refresh control circuit disabling the supply of the refresh request to the access control unit when the memory block indicated by the refresh address matches the memory block corresponding to the refresh mode part in which the disable is set, and enabling the supply of the refresh request to the access control unit when the memory block indicated by the refresh address matches the memory block corresponding to the refresh mode part in which the enable is set.

15. The system according to claim 14, wherein
when the cell mode information in the cell mode part is changed to information indicating the twin-cell mode from that indicating the single-cell mode, the access control unit operates the corresponding memory block in the twin-cell mode after operating it in a transitional twin-cell mode until all of the memory cells in the corresponding memory block are accessed, and
the transitional twin-cell mode is an operation mode to retain data retained in one of the pair of memory cells as the complementary data in the pair of memory cells by starting access to one of the pair of memory cells and then starting access to other of the pair of memory cells.

16. The system according to claim 15, wherein the access control unit comprises:
a transition detection circuit activating a transition detection signal in each of the memory blocks when the cell mode information in the cell mode part is changed to information indicating the twin-cell mode from that indicating the single-cell mode;
an access detection circuit outputting an access finish signal when all of the memory cells in the corresponding memory block are accessed after the activation of the transition detection signal; and
a mode change circuit changing the operation mode of the corresponding memory block from the single cell mode to the transitional twin-cell mode in response to the transition detection signal and changing the operation mode of the corresponding memory block from the transitional twin-cell mode to the twin-cell mode in response to the access finish signal.

17. The system according to claim 15, wherein
the refresh control unit includes a refresh address counter sequentially generating a refresh address indicating the memory block and the memory cell on which the refresh operation is performed in response to the refresh request, and
the access detection circuit detects that all of the memory cells in the corresponding memory block are accessed by monitoring the refresh address generated by the refresh address counter.

18. The system according to claim 10, wherein the semiconductor memory comprises:
a refresh request generation circuit periodically generating the refresh request, and wherein
the refresh control circuit performs the refresh operation in response to only the refresh request generated by the refresh request generation circuit.
